(19) United States
(12) Patent Application Publication
(10) Pub. No.: US 2015/0118441 A1
(43) Pub. Date: Apr. 30, 2015

(54) THERMO-PHOTO-SHIELDING FOR HIGH TEMPERATURE THERMAL MANAGEMENT

(71) Applicant: GENERAL ELECTRIC COMPANY, Schenectady, NY (US)

(72) Inventors: Wen Shang, Shanghai (CN); Tao DENG, Shanghai (CN); Boris RUSS, Berkeley, CA (US); Hendrik Pieter Jacobus DE BOCK, Clifton Park, NY (US); Adam RASHEED, Glenville, NY (US); Andrew Arthur Paul BURNS, Niskayuna, NY (US); Mohamed SAKAMI, West Chester, OH (US); Steven Charles ACETO, Wynantskill, NY (US); Andrey MESHKOV, Niskayuna, NY (US); Scott Michael MILLER, Clifton Park, NY (US)

(73) Assignee: GENERAL ELECTRIC COMPANY, Schenectady, NY (US)

(21) Appl. No.: 14/063,733

(22) Filed: Oct. 25, 2013

(51) Int. Cl. F01D 25/00; C23C 16/00; C23C 28/00; C23C 4/00

(52) U.S. Cl. CPC F01D 25/005; C23C 4/00; C23C 16/00; C23C 28/00
USPC 428/141; 427/402; 427/446; 427/255.7; 427/430.1; 427/427; 428/220; 428/304.4; 428/312.8

(57) ABSTRACT

The present disclosure provides a multi-layer thermal protection material comprising: (i) a substrate layer; (ii) a reflection layer formed on the substrate layer; and (iii) an emission layer formed on the reflection layer and effective to convert thermal energy to photonic energy. The reflection layer comprises a porous scattering media effective to reflect photonic energy away from the substrate layer. The emission layer comprises a thermally emissive dopant incorporated into a thermal matrix material. The present disclosure also provides articles such as portions of hypersonic flight vehicles and turbine component parts that include coatings comprising the multi-layer protection material of the present disclosure. The present disclosure also provides methods of making and using the multi-layer thermal protection material and associated articles described herein.

This disclosure relates to materials, articles, and methods for use in protecting components from exposure to high heat flux and heat loading environments, such as those encountered by hypersonic flight vehicles and gas turbine hot gas path parts.

### BACKGROUND

The desire for higher-speed platforms such as air-breathing vehicles and next generation access-to-space systems has accelerated interest in hypersonic flight recently. Hypersonic flight is typically said to occur above Mach 5 where a number of phenomena ranging from thin shock layers to high-temperature effects become important. Due to the extremely high temperatures to which hypersonic flight vehicles are exposed, it is necessary to employ a thermal protection system (TPS) to protect the vehicles from such extreme heat.

In addition to practical considerations, when considering the selection of a TPS material from an aerothermal perspective, it is important to consider both the maximum heat transfer rate and total heat load. These quantities are mission specific, and the desired trajectory determines—to a large extent—the aerothermodynamic profile experienced by the vehicle. For example, heat fluxes during high speed descent of space reentry vehicles can be extreme and temperatures in excess of 1370° C. (2500° F.) can be reached, however the duration can be relatively short, thereby limiting the total heat load to the vehicle. Reentry vehicles tend to reduce most of their velocity at high altitude (in a low-density atmosphere) by following a lifting reentry from orbit. During descent through the atmosphere, the velocity is further reduced and although heat fluxes are extreme, the duration over which the structure is exposed to this load is limited to the order of minutes. Such systems are often cooled using the “insulated space vehicle” approach where insulation provides a thermal barrier to protect the vehicle's structure. The Space Shuttle is an example of such a vehicle, which used a number of specialized materials to rapidly radiate the heat back to the atmosphere during reentry.

For ultra-high-speed space vehicles returning from beyond Earth-orbit (velocities greater than ˜11 km/s), even specialized materials cannot radiate the heat fast enough. In these cases (e.g., lunar-return Apollo capsules) ablative thermal protection is used, where the ablation process is used to absorb some of the heat flux, and the gases formed from the ablation process form a protective gas layer around the reentry vehicle.

Conversely, air-breathing hypersonic vehicles in the Earth's atmosphere, such as single-stage to orbit, two-stage to orbit accelerators, and hypersonic cruise vehicles experience markedly different aerothermodynamics. Such vehicles travel at great speeds at lower altitudes to capture air for their propulsion systems. Mission lengths for such vehicles are desired to be on the order of hours. To further complicate the thermal challenge, the leading edges on such vehicles are sharp to maintain the desired vehicle aerodynamics, concentrating the thermal loads on minimal surface areas. This can result in local heat fluxes in excess of 500 W/cm² for which ablative, semi-passive (heatpipe), or actively cooled solutions are sought. Due to the harsh aerothermodynamic environment to which the vehicle is exposed, it is necessary to use advanced materials to preserve the vehicle itself, the payload, and/or the crew.

The next generation of hypersonic vehicles require more capable, durable, and maintainable TPS that are currently available, and that can absorb heat loads over prolonged mission lengths. In addition, methods that are non-sacrificial are preferred for re-useable mission profiles. Although heat-pipe, semi-passive, or active cooling systems provide additional cooling options, passive cooling systems are preferred as such systems offer reduced costs, complexity, and weight. TPS have been under development for many years to enable high-speed flight, targeting safe and cost-effective materials of highest performance in terms of high-temperature resistance, low specific weight, high mechanical strength, high resistance to plasma-chemical erosion, and high total emissivity to optimize radiative cooling. However, new generations of passive TPS are needed to extend the range of current passive capability and to address the needs of tomorrow's hypersonic vehicles.

Beyond the realm of hypersonic flight, passive thermal protection at high temperatures is of critical concern in the design of jet engines and gas turbines, where higher operating temperatures hold the promise of greater efficiency. Although some of the success criteria are different for these two fields (e.g., longer lifetimes and harsher cycling environments in turbine applications), the fundamental need for robust, high temperature coatings is universal.

There have been various approaches to managing surface temperature in hypersonic applications. In all cases, surface heating is a combination of convective heating and radiative heating, where radiative heating is minimal for most hypersonic applications (other than beyond Earth-orbit reentry).

An illustrative approach is the one used on the space shuttle where a low-temperature structure is insulated and the entire temperature gradient occurs across the insulation layer. The incoming heat-flux is aggressively re-radiated back to the atmosphere, thereby protecting the underlying structure. This approach is favored for systems where heat loads are high but are only applied for short duration. However, a key drawback is the need for an entire extra thick layer of material to protect the vehicle. This adds complexity, as well as a significant weight penalty, that limits vehicle performance. Another illustrative approach is the one used on the X-15 where the structure re-radiates some of the heat and absorbs some of the heat, thereby avoiding the need for additional insulation material. This can be applied for moderate heat flux conditions for short to medium durations. Yet another illustrative approach is the hot structure approach used on the SR-71 wherein the entire structure heats up, resulting in relatively low heat flux to the structure, allowing for a higher overall heat load for long durations. This approach, however, places higher requirements on the structural materials with few practical options available. For example, the SR-71 used titanium (which has a maximum useful temperature of approximately 426° C. (800° F.)) which limited the SR-71 to Mach 3 flight. Thus, the hot structure approach is limited by the materials used in vehicle design, and it is desired to extend the capabilities of TPS for the next generation of hypersonic vehicles.

There have been efforts attempting to use radiation shielding or reflective layers in the past as stand-alone means to lower heat flux. For example, the SMARF MLI used silica-based paper stabilized with alumina-based adhesive for reflective layers. Gold or platinum was used as a reflective coating layer to extend temperature capability to 1650° C. (3000° F.); these structures survived six temperature cycles while keeping the back-face temperature at 250° F. However, assembly was difficult and required generating vacuum between layers with good sealing. The complexity of fabrication and assembly of multiple layers was a major challenge to the implementation of this design. Further, the noble metal layers were found to be microstructurally unstable over extended thermal cycling.

The environment within the hot gas path of a modern turbine (for aerospace or energy) is currently dictated by the thermal stability of the materials used to fabricate the turbine (e.g., superalloys, ceramic matrix composites). One of the ways to regulate the hot gas path temperature is through the use of a stoichiometric excess of air in the fuel mixture to dilute the hot gases, which limits the efficiency of the overall cycle. Thus, a large effort over the past several decades has been devoted to increasing in the thermal capabilities of the hot gas path materials through thermal barrier coating (TBC) development and other thermal management technologies, which enable higher combustion temperatures, minimize cooling air requirements and enhance efficiency.

Thermal barrier coatings deposited on metals (e.g., superalloys) are traditionally composed of a thin (75-150 μm) bond coat layer incorporating an oxidation resistant metal alloy (e.g., NiₓCr_{y}AlY, PtAl), followed by a ceramic surface layer (100-400 μm) chosen to have a low thermal conductivity. Over time, a third layer grows at the interface (˜10 μm) between the bond coat and the topcoat, known as the thermally grown oxide (TGO) which acts to further passivate the coating to oxygen permeation. A range of methods and materials have been applied to the development of thermal barrier ceramic coatings, but the dominant materials system remains yttrium-stabilized zirconia largely due to its extremely high thermal stability (2700° C. melting point), reasonable thermal expansion coefficient (˜11×10⁻⁶/° C.) and low thermal conductivity (2.3 W/m·K, bulk).

As described above, at elevated temperatures, the major modes of heat transfer in thermal barrier coatings are conductive (phonons) and radiative (photons). One method of enhancing thermal performance (i.e., reducing thermal conductivity) is the incorporation of phonon and photon scattering sites, such as vacancies or impurity atoms in the TBC matrix. An interesting take on this is the use of multilayer thermal barrier coatings in which alternating materials or material compositions (e.g., densities) are introduced to prevent phonon and photon propagation within the material, leading to significantly reduced thermal conductivities.

There continues to be a need to develop more effective materials and methods for protecting components such as hypersonic flight vehicles and internal gas turbine hot gas path parts from extremely harsh thermal environments. Existing materials used in these applications tend to have a variety of drawbacks, including weight, durability, and reusability concerns. Some current approaches to this issue have involved using low thermal conductivity coatings that only focus on engineering bulk thermal conductivity or using high emissive coatings that only focus on emissivity engineering.

There is a need for a thermal protection system for high temperature environments that both (i) modifies the boundary condition (e.g., lowers the heat flux to the surface) and (ii) is itself a material that is resistant to very high temperatures. To date, there appear to be no reusable materials that address the TPS challenge from both these aspects.

The present system and techniques are directed to overcoming these and other deficiencies in the art.

### SUMMARY

The present disclosure relates to materials, articles, and methods useful for protecting components and materials from thermal destruction or degradation due to exposure to extremely high temperatures, including those components and materials used in hypersonic vehicles and internal combustion turbine engines.

According to one aspect, the present disclosure provides a multi-layer thermal protection material comprising: (i) a substrate layer; (ii) a reflection layer formed on the substrate layer, said reflection layer comprising a porous scattering media effective to reflect photonic energy away from the substrate layer; and (iii) an emission layer formed on the reflection layer and effective to convert thermal energy to photonic energy, said emission layer comprising a thermally emissive dopant incorporated into a matrix material.

In one embodiment, the substrate layer of the multi-layer thermal protection material comprises a ceramic, a ceramic matrix composite, a metal, or combinations thereof. In another embodiment, the reflection layer of the multi-layer thermal protection material comprises a porous ceramic, a metal, or combinations thereof. In a further embodiment, the emission layer of the multi-layer thermal protection material comprises a doped ceramic. In another embodiment, the emission layer can have a surface that is either textured or non-textured.

In one embodiment, the multi-layer thermal protection material further comprises one or more interfacial layers interposed between the substrate layer and the reflection layer to minimize thermal expansion coefficient mismatch or enhance adhesion between the substrate layer and the reflective layer.

According to another aspect, the present disclosure provides an article comprising: (i) a base; and (ii) a multi-layer thermal protection material according to the present disclosure formed on said base, wherein the substrate layer of the multi-layer thermal protection material is proximate to the base. In one embodiment, the article further comprises a bonding layer formed between the base and the substrate layer of the multi-layer thermal protection material. In a particular embodiment the base comprises at least a portion of a surface of a hypersonic flight vehicle, a component part of a turbine engine, or other high temperature environment. In another embodiment, the component part of the turbine engine is selected from the group consisting of a nozzle, a turbine blade, a vane, a combustion liner, a shroud, a bucket, and a transition piece.

According to another aspect, the present disclosure provides a method for producing a thermally protected article that involves the steps of: (i) providing a base having an outer surface; and (ii) forming the multi-layer thermal protection material according to the present disclosure on said base, where the multi-layer thermal protection material is layered onto the base beginning with the substrate layer. In one embodiment, the method further comprises forming a bonding layer between the base and the multi-layer thermal protection material.

The present disclosure provides a TPS that involves a hot structure approach, while enhancing the conversion of incident energy to thermal photons which may be radiated away to minimize the heat absorption into the hypersonic vehicle. In particular, in one embodiment, the thermo-photo-shielding approach of the present disclosure combines the radiation benefits of the hot structure approach while providing sufficient insulation to allow applicability of ceramic matrix composites (CMCs) in the structure in hypersonic applications. Specifically, this approach isolates a thin thermo-photoemissive layer, which can handle extreme temperatures, as the outermost layer of the TPS. By having this outer layer reach extreme temperatures, radiation from the outer surface is maximized. The temperature capability of candidate outer layer matrix materials such as YSZ, MgO or rare earth oxide materials can be >1925° C. (3500° F.), reaching effective radiative capabilities of >130 W/cm².

In order for the outer thermo-photoemissive layer to reach such temperatures while maintaining substrate temperatures in the range of 1200-1315° C. (CMC thermal limit depending on application and environment) significant thermal shielding is required. This shielding is supplied by a layer of a low thermal conductivity material, such as a yttria-stabilized zirconia (YSZ) thermal barrier coating. Tuning YSZ porosity offers a path to further reduce the thermal conductivity of this insulation layer. By increasing the void ratio, the thermal conductivity can be reduced to approach near vacuum levels, though with some loss of strength versus a densified layer. To reduce potential back radiation from the hot outer layer to the CMC structure, the presently disclosed porous structure will act to scatter and reflect the emitted photons back to the outer layer, thus limiting the propagation of radiative heat flux into the structure.

These and other objects, features, and advantages of the present methods, systems, and techniques will become apparent from the following detailed description of the various aspects of the present disclosure taken in conjunction with the accompanying drawings.

### BRIEF DESCRIPTION OF THE DRAWINGS

FIG. 1. is a schematic view of one embodiment of a multi-layer thermal protection material according to the present disclosure. The multi-layer thermal protection material includes a substrate layer, a reflection layer formed on the substrate layer, and an emission layer formed on the reflection layer.

FIG. 2 is a schematic view of one embodiment of an article having a multi-layer thermal protection material formed in accordance with the present disclosure. The article includes a base and a multi-layer thermal protection material of the present disclosure formed on the base.

FIG. 3 is a schematic view of one embodiment of an article having a multi-layer thermal protection material formed in accordance with the present disclosure. The article includes a base, a multi-layer thermal protection material of the present disclosure formed on the base, and a bonding layer formed between the base and the substrate layer of the multi-layer thermal protection material of the present disclosure.

FIGS. 4A-4B show a YSZ specimen with two different porosities achieved under two different processing conditions. FIG. 4A shows YSZ samples sintered with a fast ramp rate in dry H₂ (1% porosity). FIG. 4B shows YSZ samples sintered with a fast ramp rate in argon (30% porosity).

FIG. 5 is a graph showing reflectivity vs. porosity for YSZ under different processing conditions. As shown, FIG. 5 illustrates reflectivity at 2 μm wavelength vs. porosity for _{Y}SZ samples sintered under different atmospheres and ramp rates.

FIG. 6 is a graph showing change in reflectivity upon long term annealing at 1800° C. (3272° F.).

FIG. 7 is a graph showing measured emittance at 8.94 μm for samples of various CeO₂ content.

FIG. 8 is a graph showing measured emittance at 3.6 μm for samples of various CeO₂ content.

FIG. 9 is a graph showing measured emittance at 2.4 μm for samples of various CeO₂ content.

FIG. 10 is a graph showing measured temperature gradients for 20% by mole CeO₂ stabilized hafnia and 20 mole percent ceria doped YSZ.

FIG. 11 is a schematic diagram representing the emission of photons from within the TPS material, showing the range of angles over which the light will be radiated (shaded triangle) for a perfectly flat interface between YSZ and air.

FIGS. 12A-12B illustrate modeling results for light extraction efficiency for materials. FIG. 12A is a schematic of the optical model for cubic packing of 100 μm diameter features (holes or posts) with 100 μm spacing between features. FIG. 12B is a graph showing ray tracing modeling results of a comparison of hole and post texture geometries.

FIG. 13 is a graph showing thermal gradient measurements for abrasively roughened single crystal YSZ.

FIGS. 14A-14C are photographs of post/trough surface textures generated by laser machining in single crystal YSZ (FIG. 14A), neat polycrystalline YSZ (FIG. 14B), and CeO₂-doped polycrystalline YSZ (FIG. 14C). The sample in FIG. 14A is 1 cm×1 cm×1 mm, and the samples in FIGS. 14B and 14C are 6 mm diameter by 1.3 mm thick.

FIG. 15 is a graphical diagram showing optical profilometry of laser machined single crystal YSZ.

FIGS. 16A-16B are graphical diagrams showing optical profilometry of polycrystalline pure YSZ (FIG. 16A) and polycrystalline 5 mol % CeO₂-doped YSZ (FIG. 16B).

FIG. 17 is a graph showing ΔT for a partially surface textured sample indicating higher ΔT for heating from the unpatterned side than from the patterned side, potentially indicating higher effective emissivity.

FIG. 18 illustrates optical images (left) and optical profilometry surface reconstructions (right) for laser textured single crystal materials with various texture geometries.

FIGS. 19A-19C are micrographs showing Scanning Electron Microscopy imaging of laser textured single crystal YSZ with ˜50 μm spaced pits of ˜8 μm depth (FIG. 19A) compared to the untextured area above. The material surface exhibits nanoscale re-deposition of YSZ surrounding the laser drilling sites (FIG. 19B) and significant roughening of the interior of the laser drilled holes to generate ˜100 nm pores and trenches in addition to the nanoscale re-deposition seen elsewhere on the sample (FIG. 19C).

FIG. 20 is a graph showing a plot of measured ΔT per mm for two-half patterned (pitted) YSZ single crystal samples.

FIG. 21 is a photograph of a single crystal YSZ after laser heat treatment with half the surface textured with a square array of holes, with a large amount of internal cracking

FIG. 22 is a graph showing measured spectral emittance of patterned and un-patterned areas of the single crystal YSZ sample shown in FIG. 19 at an uncorrected temperature of 1740° C.

FIG. 23 is a graph showing x-ray analysis of heat treated CeO₂/YSZ Powder highlighting the bulk of the material in a homogeneous CeO₂-doped YSZ phase (light arrows) and a minority in the parent YSZ phase (dark arrows).

FIG. 24 is a graph showing thermal performance (back-side temperature) comparison between single-layer CeO₂-doped YSZ and multilayer CeO₂-doped YSZ samples at the same torch settings (same heat flux) showing lower back-side temperatures for multilayer samples than for single layer samples of greater thickness.

### DETAILED DESCRIPTION

In general, the materials, articles, and methods of the present disclosure address problems associated with the exposure of hypersonic flight vehicles and turbine engine component parts to extremely high temperature environments. As discussed in more detail below, the present disclosure includes multi-layer thermal protection materials, articles that include the multi-layer thermal protection materials, and methods of producing thermally protected articles from the multi-layer thermal protection materials.

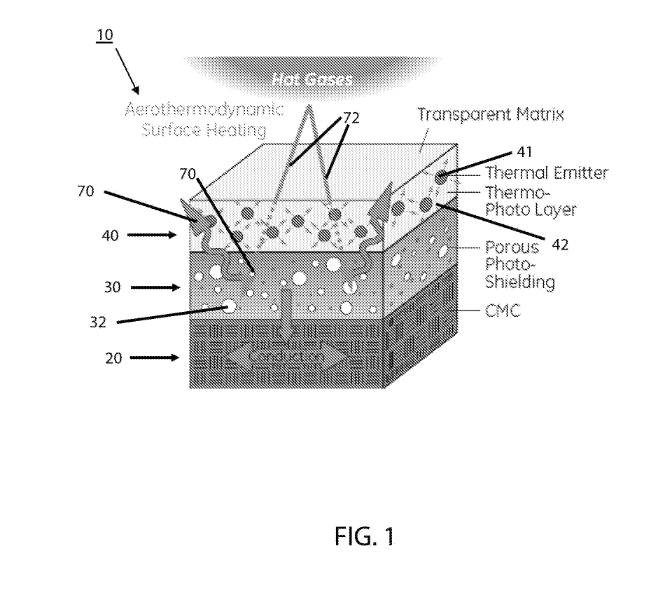

Referring now to FIG. 1, an exemplary multi-layer thermal protection material 10 is illustrated. As shown in FIG. 1, multi-layer thermal protection material 10 includes substrate layer 20, reflection layer 30 formed on substrate layer 20, and emission layer 40 formed on reflection layer 30. Reflection layer 30 comprises a porous scattering media 32 effective to reflect photonic energy 70 away from substrate layer 20. Emission layer 40 includes a thermally emissive dopant 41 incorporated into a thermal matrix material 42, and is effective to convert thermal energy 72 to photonic energy 70.

In one embodiment, the multi-layer thermal protection material of the present disclosure may have a bulk thermal conductivity of between about 0.1 and about 3.0 W/m·K.

The multi-layer thermal protection material of the present disclosure may have an overall thickness of between about 100 and about 5,000 micrometers. The substrate layer may have a thickness of between about 1 and about 500 micrometers. The reflection layer may have a thickness of between about 100 and about 1000 micrometers. The emission layer may have a thickness of between about 5 and about 250 micrometers.

The substrate layer of the multi-layer thermal protection material may comprise a ceramic, a ceramic matrix composite, a metal, or combinations thereof. Examples of suitable ceramics include, without limitation, zirconia, hafnia, alumina, magnesia, ceria and dopant stabilized versions thereof (including, but not limited to yttrium-, calcium-, cerium-, lanthanide- or magnesium-stabilized). Examples of suitable ceramic matrix composites include, without limitation, Silicon Carbide/Silicon Carbide, and Silicon/Silicon Carbide. Examples of suitable metals include, without limitation, superalloys such as Inconel, Rene N5, Rene N6, CMSX-10, CMSX-10, and Hasteloys.

The reflection layer of the multi-layer thermal protection material may comprise a porous ceramic, a metal, or combinations thereof. Examples of suitable porous ceramics include, without limitation, porous yttrium-stabilized zirconia (YSZ), porous yttrium-stabilized hafnia, porous calcium-stabilized zirconia, porous lanthanide-stabilized zirconia, porous lanthanide-stabilized hafnia and porous magnesia. In one embodiment, the reflection layer has a grey emissivity of between about 0.4 and about 1.0, and a thermal conductivity of between about 0.1 and about 3.0 W/m·K.

As noted herein, the emission layer of the present disclosure includes a thermally emissive dopant incorporated into a thermal matrix material. In one embodiment, the thermal matrix material is transparent to dominant wavelengths radiated by the thermally emissive dopant.

Examples of suitable thermal matrix materials include, without limitation, yttria-stabilized zirconia (YSZ), yttrium-stabilized hafnia, lanthanide-stabilized zirconia, lanthanide-stabilized hafnia, calcium-stabilized zirconia, and calcium-stabilized hafnia.

Examples of suitable thermally emissive dopants include, without limitation, elements such as cerium (Ce), nickel (Ni), holmium (Ho), neodymium (Nd), samarium (Sm), erbium (Er), ytterbium (Yb), thulium (Tm), cobalt (Co), and mixtures thereof. In various particular embodiments, the thermally emissive dopant can include, without limitation, CeO₂, Nd₂O₃, Sm₂O₃, Er₂O₃, Yb₂O₃, Tm₂O₃, Co₃O₄, and NiO.

In one embodiment, the emission layer comprises a doped ceramic. Examples of suitable doped ceramics include, without limitation, CeO₂-doped YSZ, Cerium-doped hafnia, lanthanide-doped hafnia, lanthanide doped zirconia, among other dopants listed above.

In one embodiment, the emission layer of the multi-layer thermal protection material has a grey emissivity of between about 0.7 and about 1.0, and a thermal conductivity of between about 0.1 and about 3.0 W/m·K.

The multi-layer thermal protection material of the present disclosure is a unique material designed to intensely radiate away heat in order to protect any underlying component. The present disclosure also provides embodiments that use a micro-textured surface in order to improve the thermal protective characteristics of the multi-layer thermal protection material of the present disclosure. In accordance with the present disclosure, a carefully designed micro-surface can also absorb the acoustic energy that causes boundary layer transition from laminar to turbulent which would reduce the heat load by up to five times. For hypersonic flows (M>4) boundary layer transitions from laminar to turbulent state due to acoustic instability within the boundary layer. The micro-textured surface used in the multi-layer thermal protection material of the present disclosure can both maximize the thermal rejection of the thermo-photo-shield, as well as minimize the heat load, thereby addressing both aspects of the thermal protection system challenge (developing a material able to withstand the heat and reducing heat load).

Therefore, in accordance with one embodiment, the present disclosure provides an emission layer that can have a surface that is either textured or non-textured. In one embodiment, the surface of the emission layer is textured and incorporates features on the order of 50-500 μm depth and 50-500 μm width. In one embodiment, the emission layer has a micro-textured surface effective to absorb acoustic energy. The absorption of acoustic energy by the emission layer is effective to delay the onset of transition from laminar-to-turbulent flow so as to mitigate aerodynamic heating in hypersonic flows.

In another embodiment, the multi-layer thermal protection material further comprises one or more interfacial layers interposed between the substrate layer and the reflection layer to minimize thermal expansion coefficient mismatch between the substrate layer and the reflective layer.

Examples of suitable interfacial layers can include, without limitation, barium strontium aluminosilicate (BSAS), Ni₂₂Cr₁₀AlY, and PtAl.

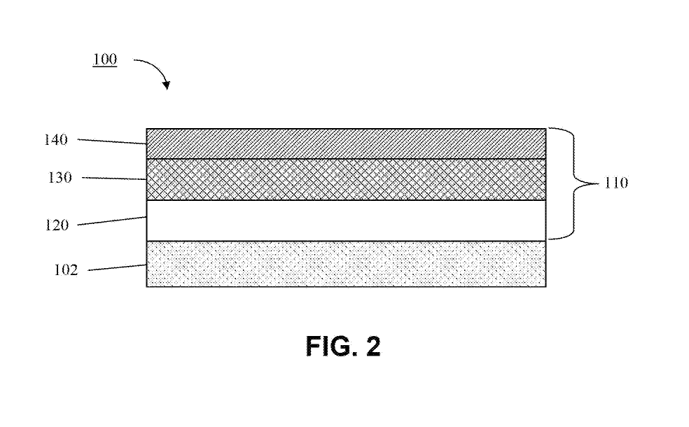

Referring now to FIG. 2, an exemplary article 100 that includes a multi-layer thermal protection material of the present disclosure is illustrated. As shown in FIG. 2, article 100 includes base 102 and multi-layer thermal protection material 110 formed on base 102. Multi-layer thermal protection material includes substrate layer 120, reflection layer 130 formed on substrate layer 120, and emission layer 140 formed on reflection layer 130. Substrate layer 120 of multi-layer thermal protection material 110 is proximate to base 102.

In a particular embodiment the base comprises at least a portion of a surface of a hypersonic flight vehicle, a component part of a turbine engine, or other surface exposed to a high temperature environment. In another embodiment, the component part of the turbine engine is selected from the group consisting of a nozzle, a turbine blade, a vane, a combustion liner, a shroud, a bucket, and a transition piece.

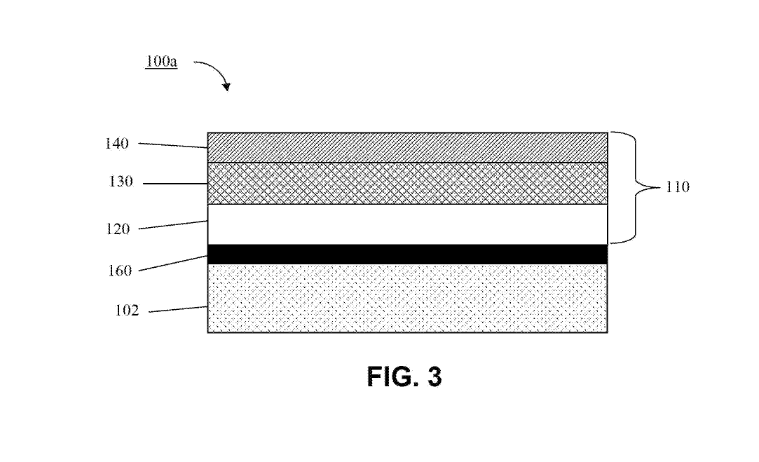

Referring now to FIG. 3, another exemplary article 100a that includes a multi-layer thermal protection material of the present disclosure is illustrated. As shown in FIG. 3, article 100a includes base 102 and multi-layer thermal protection material 110 formed on base 102, with bonding layer 160 formed between base 102 and substrate layer 120 of multi-layer thermal protection material 110. Multi-layer thermal protection material includes substrate layer 120, reflection layer 130 formed on substrate layer 120, and emission layer 140 formed on reflection layer 130. As noted, in addition to base 102 and multi-layer thermal protection material 110, article 100a further includes bonding layer 160 formed between base 102 and substrate layer 120 of multi-layer thermal protection material 110. Examples of suitable bonding layers can include, without limitation, Ni₂₂Cr₁₀AlY, PtAl, and barium strontium aluminosilicate (BSAS).

The present disclosure also provides a method for producing a thermally protected article that includes a multi-layer thermal protection material as disclosed herein. In one embodiment, this method involves the following steps: (i) providing a base having an outer surface; and (ii) forming the multi-layer thermal protection material according to the present disclosure on the base, wherein the multi-layer thermal protection material is layered onto the base beginning with the substrate layer. In a particular embodiment, the method further involves forming a bonding layer between the base and the multi-layer thermal protection material.

The multi-layer thermal protection material can be formed on the base using various deposition techniques. Suitable deposition techniques may include, without limitation, techniques involving solution plasma spray, powder plasma spray, chemical vapor deposition, dip-coating, spin casting, and combinations thereof.

As noted previously with respect to the article of the present disclosure, in accordance with the disclosed method, the base can comprise at least a portion of a surface of a hypersonic flight vehicle, a component part of a turbine engine, or other surface exposed to a hot gas environment. The component part of the turbine engine can include, without limitation, a nozzle, a turbine blade, a vane, a combustion liner, a shroud, a bucket, and a transition piece.

### EXAMPLES

The following examples are intended to illustrate particular embodiments, but are by no means intended to limit the scope of the present systems and techniques.

### Example 1

### Photo-Shielding Layer

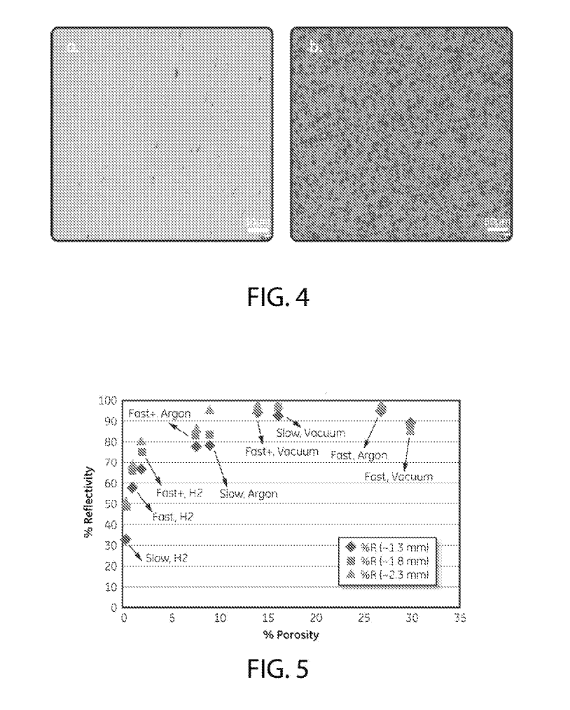

The reflective/scattering photo-shielding layer is designed to reflect the photons generated in the emissive layer away from the substrate to reduce the heat flux into the underlying layers. One embodiment of the present approach makes use of porous ceramics to scatter incident photons back to the emitting layer. Porous materials scatter light due to the refractive index difference between the bulk material and the air in the pores. FIGS. 4A-4B show a YSZ specimen with two different porosities achieved under two different processing conditions.

FIG. 5 shows reflectivity vs. porosity for YSZ under different processing conditions. The reflectivity spectra clearly show that optimum IR reflectivity can be achieved through proper engineering of the porous structure in oxide based high temperature ceramics. Pore stability at operating temperature was also studied. For ceramic materials exposed to environments with temperatures >1650° C. (3000° F.) sintering will occur continuously, which can cause structural evolution over time, with grains growing and pores disappearing.

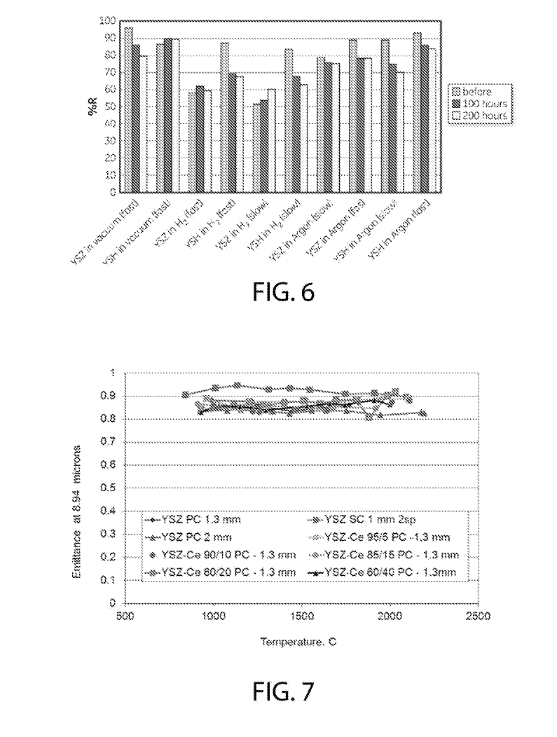

The changes in reflectivity after prolonged annealing (100-200 hours) at 1800° C. (3272° F.) are shown for both porous YSZ and porous Y₂O₃-stabilized HfO₂ (YSH) samples in FIG. 6. Reflectivity remains relatively stable after heat treatments at 1800° C. (3272° F.). The temperatures observed in hypersonic flight are generally lower than 1800° C. (3272° F.), which indicates that these ceramics should exhibit stable reflective properties in this application.

### Example 2

### Polycrystalline Doped and Undoped YSZ Samples

Spherical powders of 8 mole percent Yttria-Stabilized Zirconia were obtained from Tosoh Chemical Company (Grove City, Ohio). Nanoparticulate cerium dioxide powders (15-30 nm diameter) were obtained from NanoStructured and Amorphous Materials (Houston, Tex.). Micron-sized CeO₂ particles (3-5 μm diameter) were obtained from PIDC (Ann Arbor, Mich.).

Mixtures were prepared by dry massing of the appropriate powders and dry ball milling for at least 24 hours in a Nalgene container with YSZ-B5 5 mm diameter grinding media (Stanford Materials Corporation, Aliso Viejo, Calif.). The mass ratios used to generate the mixtures are shown below in Table 1 for representative ten gram batches of processed powder. Similar procedures were carried out to generate cerium-doped hafnia samples as well.

TABLE 1
Mass ratios for polycrystalline CeO₂/YSZ sample preparation.

| | 2.5 mol % | 5 mol % | 10 mol % | 12.5 mol % | 15 mol % | 20 mol % | 40 mol % |
|---|---|---|---|---|---|---|---|
| Composition | CeO₂ | CeO₂ | CeO₂ | CeO₂ | CeO₂ | CeO₂ | CeO₂ |
| Mass YSZ (g) | 9.68 | 9.36 | 8.73 | 8.42 | 8.12 | 7.53 | 5.34 |
| Mass CeO₂(g) | 0.32 | 0.64 | 1.27 | 1.58 | 1.88 | 2.47 | 4.66 |

The ground, mixed powders were then placed in a one inch diameter cylindrical die (˜3 g/batch), and pressed to 10,000 lbs on a bench top Carver Press (Carver Model 3912, Wabash, Ind.). After removal from the die, the discs were vacuum sealed in a plastic sleeve (Minipack-Torre MVS-31, Dalmine, IT) and isostatically pressed to 40,000 lbs/in² in an oil bath (Autoclave Engineer RL55250 isopress, Avure Technologies, Franklin, Tenn.). During thermal processing, the isopressed discs were first bisque fired to 1200° C. for 2 hours in air (10° C./min ramp rates), and then sintered in dry hydrogen using the following ramping process: 2 hours at 1200° C., 2 hours at 1500° C., and 2 hours at 1900° C. After the sintering the samples were annealed at 1500° C. for 1 hour in air to re-oxidize the reduced materials. All ramping rates during sintering and annealing were 10° C./min. Pressed and sintered pellets were ground to the desired thickness (generally 1.3 μm) with a 320 grit abrasive wheel and cut to size with a diamond core drill as needed.

### Example 3

### Thermal Measurements

A Synrad Evolution Series 100 W CO₂ laser (Mukilteo, Wash.) was used to heat ceramic samples of ˜1 mm thickness and ˜6 mm diameter. A vertically polarized laser beam of 10.59 μm wavelength was projected as a 4 mm square at the laser output aperture (becoming circular after about 1 meter). The sample was positioned about 1.5 meters from the laser, where the Gaussian full width at half maximum beam size is equal to about 9 mm due to the diffraction limited divergence angle of ˜3.5 milliradians. In this configuration about 50% of the laser power hits the sample with power density on the sample edge equal to ˜65% of that in the center.

To minimize temperature gradients between the front and the back sample surfaces, a beam splitter was used to split the laser power into two equal parts. The sample was then heated from both sides with a laser incidence angle of 45°. Because the laser beam was polarized perpendicular to the plane of incidence (s-polarization) the reflection coefficient was higher than that of the normally incident beam. This was explicitly taken into account when normal emissivity was calculated.

Two parabolic mirrors were used to image the sample using a ˜3 mm diameter aperture. The first mirror, a 90° off-axis parabolic, was mounted such that the sample was at its focal plane at 19.2 cm from the mirror center. Collimated sample radiation then passed through a 1.5″ aperture stop and was focused on an aperture with a second mirror, a 30° off-axis parabolic with parent focal length of 50.8 cm. This setup imaged the sample with a ˜2.6 fold magnification and limited the radiation collection area on the sample to a 1 mm diameter circle.

The third 90° off-axis parabolic mirror with parent focal length of 15.2 cm collimated radiation for later coupling into the Ocean Optics HR2000 200 nm-1100 nm optical spectrometer and the Nicolet 8700 FTIR (Fourier Transform Infrared) spectrometer. The diameter of the aperture stop (1) was chosen to give a ˜1 cm beam diameter at the FTIR entrance. The maximum measurement wavelength was limited by the FTIR capability to approximately 25 μm.

An Inframetrics IR760 camera with a narrow-band 8.93 μm filter was used to monitor the sample surface temperature distribution and to estimate absolute temperatures. This filter wavelength was chosen since most ceramics have high (near unity) emissivities in this wavelength region. The narrow-band nature of the filter also prevented the scattered CO₂ laser radiation at 10.59 μm from interfering with the temperature measurements.

Samples were mounted in a sample holder with three alumina rods, tapered to minimize thermal conduction. The holder was mounted on metal bar that was attached to a 3-axis linear micrometer positioner that allowed the sample to be moved in all three axes to ensure proper alignment.

### Example 4

### Thermal Emittance Measurements

As shown in FIGS. 7-10, the measured emittances at three selected wavelengths as a function of temperature are plotted for differently dopant concentrations for polycrystalline CeO₂-doped YSZ samples. The wavelengths are 8.94 μm, 3.6 μm and 2.4 μm. The long wavelength was selected to match the wavelength used by the IR camera to measure temperatures. As shown in FIG. 7, these values were essentially constant with temperature and fall within a range of 0.8 to 0.95 for various samples, enabling use of the IR camera as a robust metric for temperature in this range (assuming appropriate corrections for variations in sample emissivity).

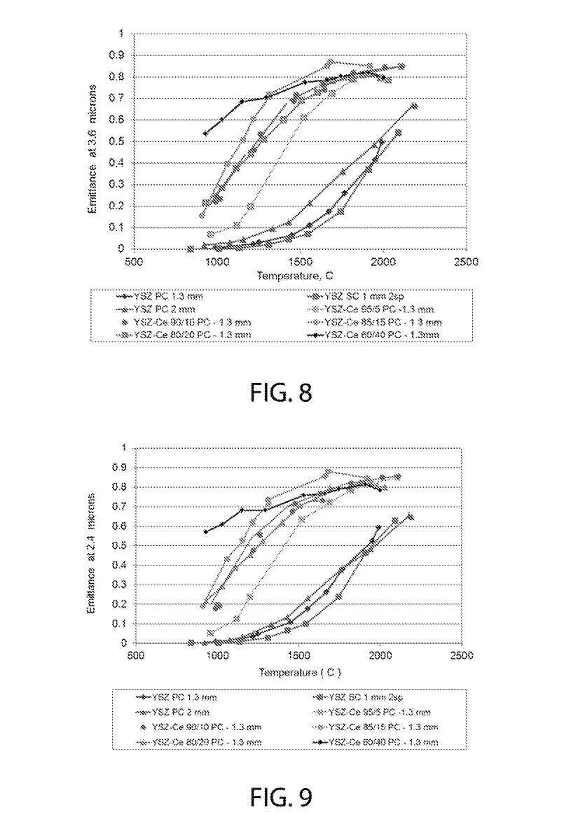

In FIG. 8 and FIG. 9 the emittance behavior of these samples at 2.4 and 3.6 μm is plotted. As can be seen, there was a distinct difference between the pure YSZ samples and those with CeO₂. The bulk of the change in emittance at low wavelengths and temperatures appeared to occur at CeO₂ concentrations of 10 mole percent and below, with limited effects beyond that range. At 40 mole percent, there was a further increase in low temperature emittance at low wavelengths, with a value above 0.5 even at the lowest temperature measured.

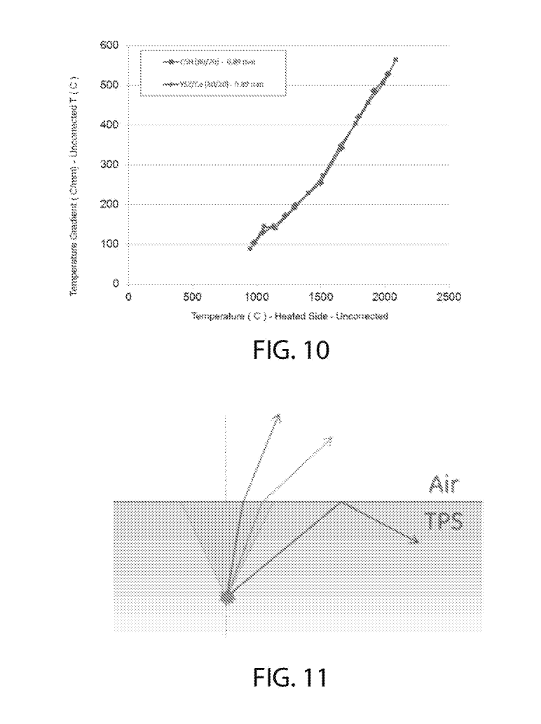

A comparison study was performed between the temperature gradients achieved by 20% by mole ceria doped YSZ and ceria stabilized hafnia (CeSH) developed on another effort, also with a 20% by mole composition, to assess performance versus other material systems. The result is shown in FIG. 10.

As shown above, the temperature gradients of the two species were virtually identical, indicating that CeO₂ dopant concentration may be effective in both oxide systems.

### Example 5

### Abrasively Roughened Surface Texture

One method of generating surface texture on polished single crystal or polycrystalline samples is simply roughening the surface of the material with an abrasive material (e.g., diamond). In this case, single crystal YSZ substrates (1 mm×1 cm×1 cm) were ground on a #120 diamond wheel for 3-5 minutes to generate roughened surfaces.

As shown in FIG. 13, the roughened sample exhibits slightly lower thermal gradient across the temperature range studied by about 30° C. over the full measurement range. This may have been due to a measurement artifact in the IR camera temperature measurements. These measurements were performed with the roughened side of the sample exposed to the ambient environment. If the roughening increased the emittance of the surface at 8.93 μm, the apparent temperature would be slightly higher on the roughened surface, thus reducing the effective ΔT across the sample.

### Example 6

### Laser Machined Surface Texture

Surface texturing via laser micromachining was carried out to fabricate microstructures onto both single crystal YSZ and polycrystalline YSZ samples. The laser micromachining was performed at GE Global Research using a 30 W 532 nm Nd:YVO₄ laser (DSH-532-30, Photonics Industries International, Bohemia, N.Y.) with pulse duration 15 ns, pulse rate of up to 150 kHz, spot size ˜50 μm and scanning speed of ˜400 mm/s.

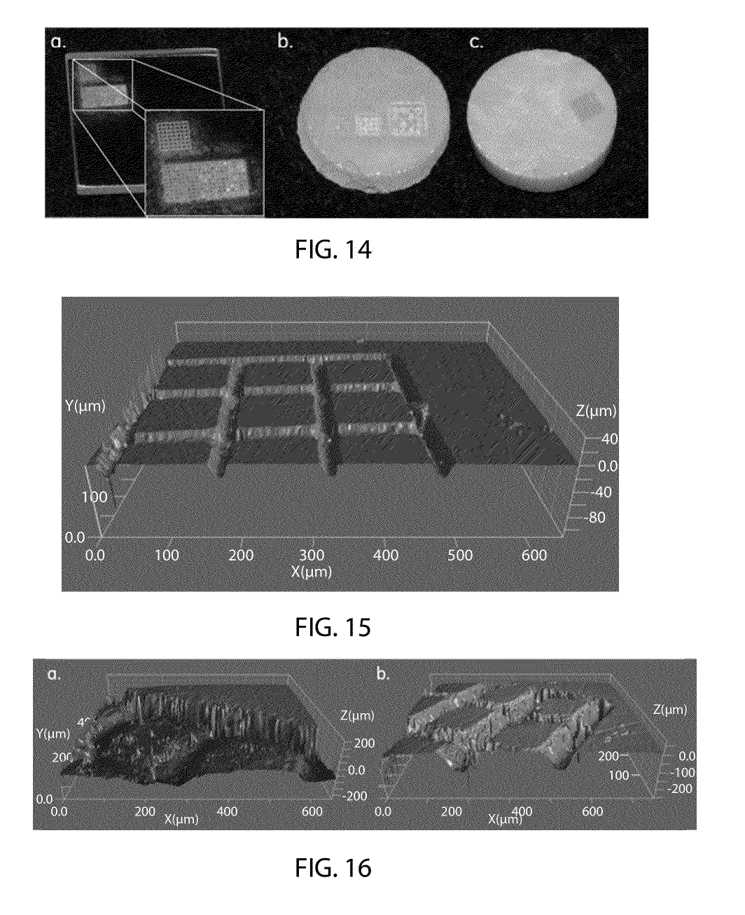

Another alternate route to generating textures at these length scales is laser micromachining The images in FIGS. 14A-14C show several microstructures generated on both single crystal YSZ (FIG. 14A), neat polycrystalline YSZ (FIG. 14B) and CeO₂-doped polycrystalline YSZ (FIG. 14C) samples.

A range of laser micromachining procedures were tested with grids of varying size. Optical profilometry measurements of the grid of trenches and islands shown in the upper left of the inset in FIG. 14A showed that the trenches were between 20-40 μm in depth, with minimal effect on the surface of the islands between trenches as shown in FIG. 15.

Similar laser micromachining experiments were performed on polycrystalline neat YSZ and 5% CeO₂-doped YSZ as shown in FIG. 15. Laser micromachining of the polycrystalline samples revealed laser-etched trenches up to 180 μm in depth, as well as noticeable erosion of the islands formed during the etching (e.g., up to 100 μm) as shown in FIGS. 16A-16B.

Interestingly, the 5% CeO₂-doped YSZ sample shown in FIG. 14C developed a discoloration in the region where the laser etching occurred (orange grid). This may have been due to differences in the ablation rates of the YSZ and CeO₂ in the material, but did not seem to deleteriously effect the ability of the material to be etched, as shown (for example) in FIG. 16B where 100 μm depth trenches were etched with no appreciable etching of the material surface on the islands between trenches.

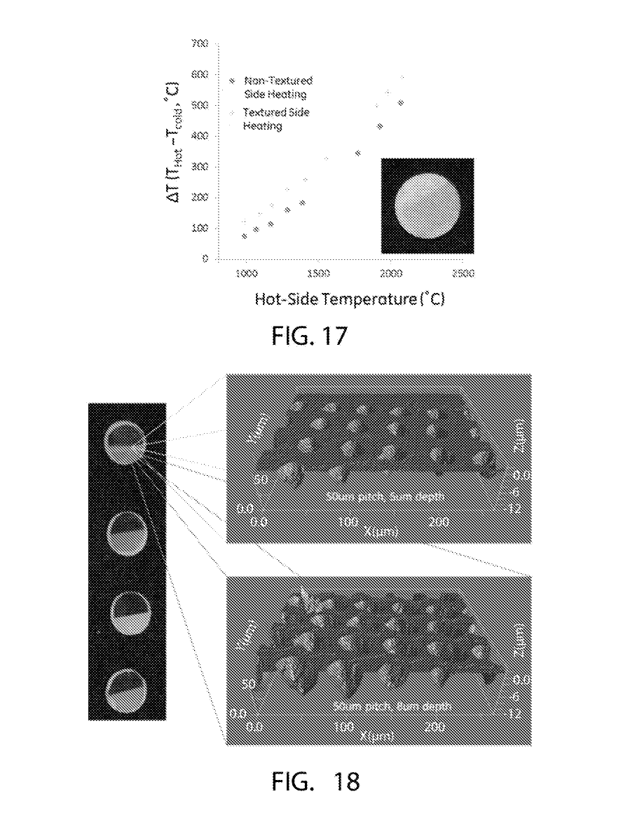

A sample of 10 mole percent CeO₂-doped YSZ was prepared with approximately half of the front surface covered in 85 μm depth, 100 μm plateau, 130 μm periodicity squares (including the center), and was tested in the CO₂ laser thermal system to determine the effect on ΔT for heating via the textured side versus the untextured side. The results are shown in FIG. 17, along with an inset image of the sample. This plot shows that there was a clear effect of texture on ΔT, with greater ΔT for heating from the patterned side, similar to the effect seen in FIG. 13. This may have been due to enhanced photoemission through the textured surface, as well as increased scattering of the incident laser beam at the surface, effectively delivering less energy to the sample, but is indicative of potential for this effect.

Based on the results shown in FIG. 17 and the modeling described in Section B of Example 5, laser texturing was again employed to generate arrays of holes of varying depth and spacing in single crystal YSZ samples. Examples of these materials are shown in FIG. 18 (left) along with the accompanying optical profilometry measurements FIG. 18 (right) that revealed 5-8 μm deep rounded holes with ˜50 μm width and ˜50 μm spacing. To simplify data analysis for these samples, the samples were textured on only half of the substrate, such that the un-textured single crystal area may act as an internal control against which any changes in emissivity or effective temperature could be measured by comparing the emission of both the textured and untextured YSZ under the same thermal load.

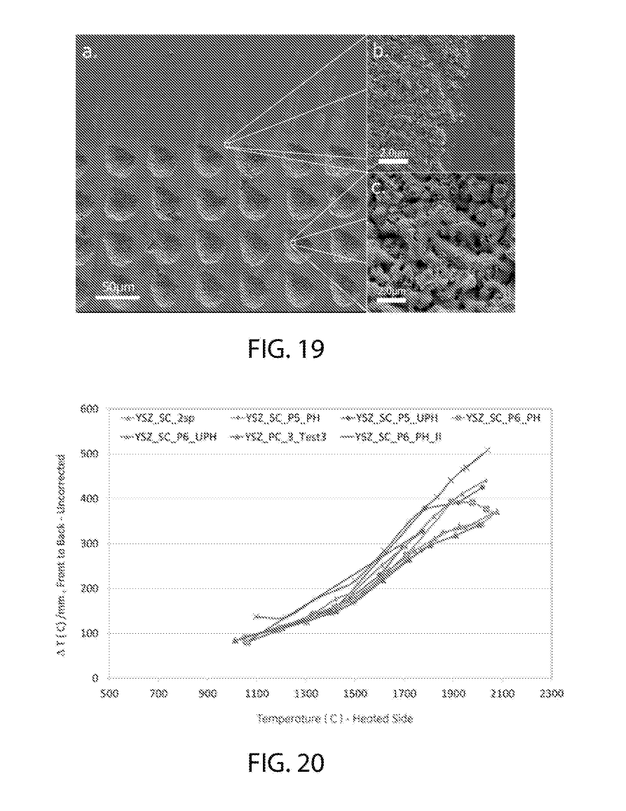

Further analysis of the samples shown in FIG. 18 by scanning electron microscopy revealed a significant amount of ejected material re-deposited on the surface adjacent to the laser drilled holes. This material generated a nano-rough surface with particulate material made up of grains in the tens of nm as shown in FIG. 19B. In the textured pits, the topology is more varied, with noticeable porosity and undulations in the surface (300-500 nm size) in addition to the nanometric grains of material seen throughout FIG. 19C. All of these effects combined to generate a large number of potential scattering sites for light propagating through the TPS materials and a greater range of possible angles for photon emission than for a flat, polished single crystal material, potentially enhancing the thermal dissipation of the TPS coating.

As above, the samples were measured for ΔT in two configurations. The first configuration heated the patterned side of the sample, while the second heated the sample from the un-patterned side. The measured gradients in ° C./mm are plotted in FIG. 20. The designations UPH and PH are indicators of the side heated with the laser, UPH (un-patterned side heated) and PH (patterned side heated). The designation II indicates a repeat measurement of the sample.

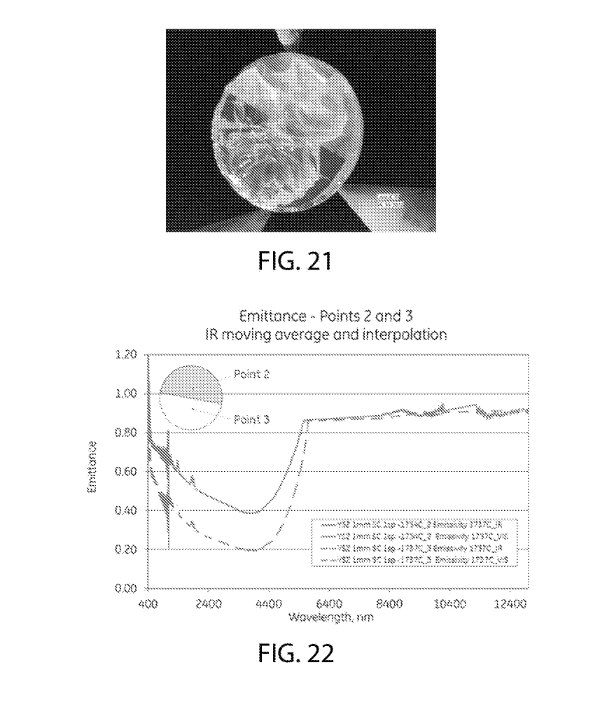

The second run of the sample YSZ_SC_P6 showed an increase in the measured temperature gradient. This may have been due to increased cracking in the sample. The single crystal samples showed significant cracking during the test as shown in FIG. 21.

Determining the effect on the temperature of the sample was, however, more complicated, as the emittance of the samples at the IR camera measurement wavelength was subject to change by the patterning.

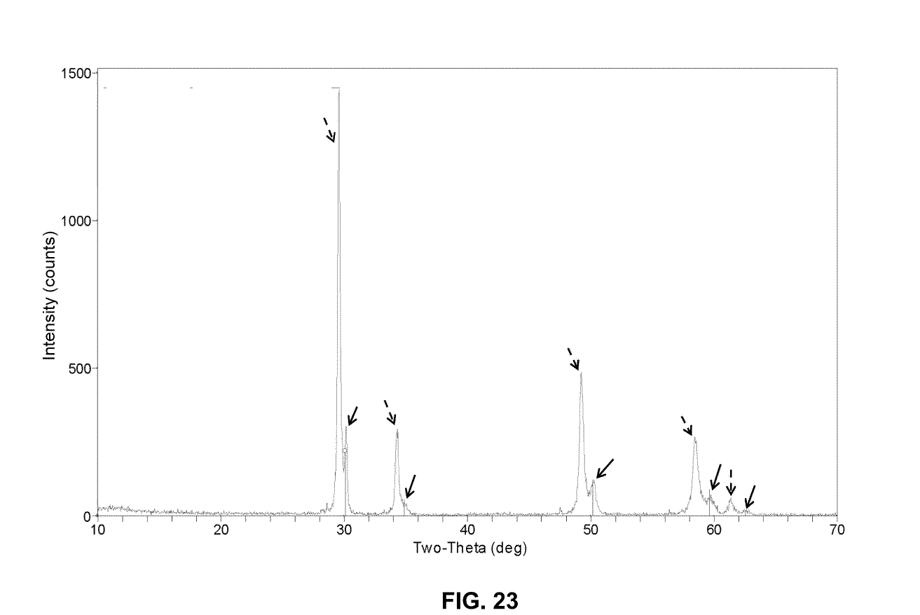

In an effort to better understand this measurement, the emissivities of the patterned and unpatterned areas of the sample were measured at the wavelength used by the IR camera to determine the sample temperature (8.93 μm). These results are shown in FIG. 23. The spectral results were smoothed via a moving average and interpolation to remove measurement artifacts from 1) scattering from the laser into the detector and 2) absorption from atmospheric.

The red line in FIG. 23 is the measured emittance at point 2 (patterned area) and the blue is the emittance measured at point 3 (un-patterned area). The emittance was approximately 0.01 higher at the IR camera wavelength of 8.93 mm on the patterned side. This emittance was used to correct the IR camera images, resulting in the temperature profile shown in FIG. 23 (across both the patterned and unpatterned halves).

### Example 7

### Surface Texturing

Because photoemission is an isotropic process, for an emissive material with a flat external surface, photons generated within the material will encounter the outer surface at a range of incident angles. Beyond a certain critical angle of incidence (θ_{C}, Equation 11) Snell's Law states that the incident photons will be totally internally reflected (TIR) by the interface back into the material, which will limit radiative heat loss. For the system of yttria-stabilized zirconia, with an index of refraction of 2.15 (at room temperature and visible wavelengths), the critical angle is 26.7° from the surface normal. Thus all light rays incident outside of that cone will be totally internally reflected, limiting the amount of energy which can be dissipated as depicted schematically in FIG. 11.

$${θ}_{C} = {sin}^{- 1} ( \frac{{η}_{air}}{{η}_{TPS}} ) \qquad ( 1 )$$

Several techniques to address the challenge of light extraction have been demonstrated to mitigate the effects of total internal reflection. Two fundamental approaches were pursued. The first was based on the fact that reflection occurs at the abrupt interface of materials of different refractive indices and is a function of the difference in refractive index between adjacent materials at an interface. Anti-reflective coatings have been developed in the optics industry, which generate a gradient of refractive index from the bulk material to the ambient environment via deposition of one or more layers of materials of intermediate refractive index. These multi-layer coatings can be quite effective in mitigating TIR in room temperature applications, but the high temperature environment of hypersonic flight limits the applicability of such films. Specifically, the range of refractive indices available in high temperature materials is limited, and the mismatch of thermal expansion coefficients would likely make it difficult to build multilayer films for high temperature applications.

Another option to enhance light extraction is the use of surface texture, for example hemispheric pits or protrusions at the material surface. This concept is known as micro-lensing and mitigates total internal reflection by ensuring that most photons incident at the TPS-air interface will be incident at angles below θ_{C}. For example, this technique has been applied to the development of high efficiency organic light emitting diodes to enhance light out-coupling efficiency (e.g., enhancing by 150-200% depending on refractive index and emitter geometry).

Several techniques were pursued for the integration of surface texture into the TPS coatings (see Examples 5-6 for methods) with two broad categories of texture. Work began with methods that generate random surface patterns, based on the spray deposition (and subsequent annealing) of particulate YSZ onto single crystal surfaces to introduce a random texture and an effective gradient in refractive index. Sintering of these materials tended to reduce the anti-reflective effect of the surface treatment (effectively smoothing the surface), so abrasive roughening of single crystal YSZ samples was also considered. Additionally, two surface structuring techniques to enable specific control over the geometry of the surface were tested. First, laser ablation was used to etch pits of specified size and placement into single crystal and polycrystalline samples. Finally, a technique for direct embossing of ridge textures into polycrystalline samples during production was developed.

Light extraction efficiency is a function of the material, the general geometry of surface texture, as well as the relative size of the texture with respect to the wavelength of light interacting with it. Thus, to enhance infrared photoemission in this application, team chose to model the interaction of various surface textures in YSZ to determine the appropriate textures to generate via laser machining.

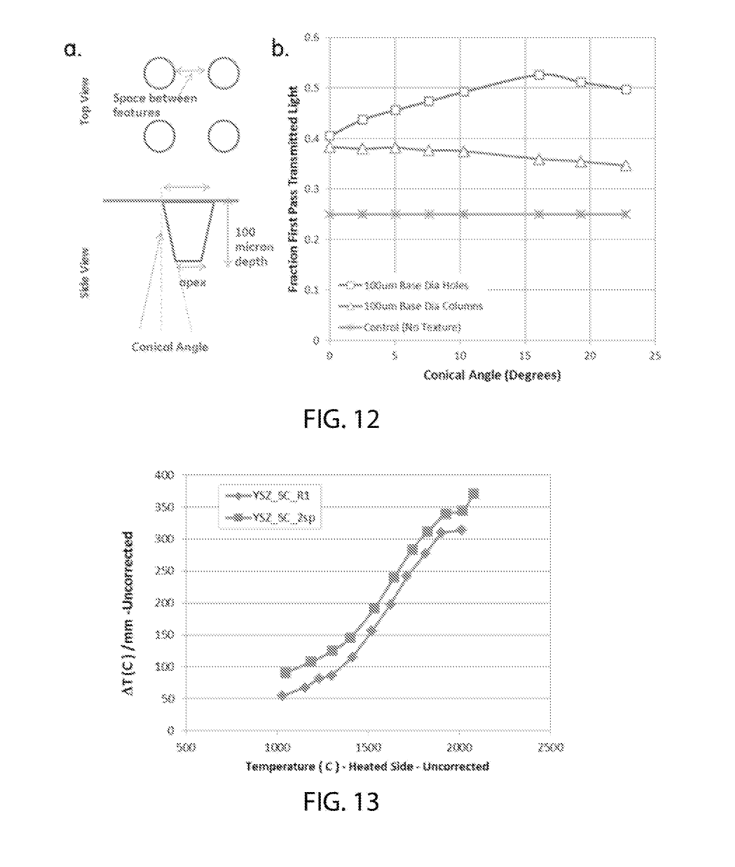

Optical ray tracing was used to model the effect of different texture features. For a given object spacing of 100 μm, detailed in FIG. 12A, modeling showed the light extraction efficiency to be higher for an array of holes, when compared with a similarly arranged array of posts or an optically flat surface as shown in FIG. 12B. Based on the results of this modeling, the team ultimately chose to pursue laser texturing with arrays of pits, though both pit and post structures were generated via laser texturing.

To enhance photoemission from the TPS material, a range of surface texturing approaches were considered during the course of this work including powder spray coating, laser machining and embossing as described below. All of these approaches may be thought of as ways to generate a gradient of refractive index between the bulk material and the environment, or by creating surfaces with a variety of orientations to minimize the effects of total internal reflection.

### Example 8

### YSZ/CeO₂ Plasma Sprayed Coatings

A 25 mol % CeO₂/YSZ mixture was prepared by shaker-mixing a combination of 15-30 nm diameter CeO₂ nanopowder (NanoStructured and Amorphous Materials) with a 0.55-0.75 μm diameter 8 mol % YSZ powder (UCM Advanced Ceramics, 8%-Y Zirconia-1 um HP) for 30 minutes to ensure mixing of the two components. This mixture was placed in an alumina crucible and fired at 1550° C. for 8 hours under air which acted to inter-diffuse the two species. X-Ray Diffraction analysis in FIG. 23 shows that after 8 hours there is nearly complete incorporation of the two species into a homogeneous crystal structure (yellow arrows) with only a small portion of remnant YSZ (green arrows).

The resulting ceramic material (densified by a factor of two) was then broken down into a powder and ball milled for 90 hours to return to the original 0.5-0.75 μm diameter size distribution. The resulting powder was combined into an aqueous slurry containing 20 wt. % powder which was deposited via solution plasma spray deposition at gun-to-sample distances of 3.5 inches at 90 kV accelerating voltage.

### Example 9

### Ceramic Matrix Composite Coatings

Five samples of SiC/SiC ceramic matrix composite (CMC) materials were obtained from GE Ceramic Composites as six inch square panels (0.07 inch thickness). Four of these samples were coated with a GE proprietary environmental barrier coating (EBC) via plasma spray deposition. The fifth was retained as a control for the thermal properties of the underlying CMC. In this case, the EBC performs two functions—specifically preventing exposure of the CMC material on the hot side during testing and creating a buffer between the relatively high coefficient of thermal expansion of YSZ (˜10×10⁻⁶/K) compared to SiC (˜5-6×10⁻⁶/K).

Two EBC-coated plates were plasma spray coated with a layer of high porosity neat YSZ, masked such that a range of YSZ thicknesses were achieved (targeting 100-500 μm) in three steps. These coated plates were then rotated 90° and a similar masking scheme used to deposit three different thicknesses of the TPS layer described above, generating a range of nine conditions on each plate. The remaining two EBC-coated plates were similarly coated with three different thicknesses of the YSZ/CeO₂ material.

Coated CMC parts were tested in a computer-controlled torch heating (hydrogen-oxygen or natural gas-oxygen flame) system capable of heating the front surface of a sample and cooling the back surface via forced gas (air). The front surface of the sample can be heated up to temperatures above 1650° C. (3000° F.), depending on the sample properties and backside cooling requirements. To illustrate the difference in materials performance at the same torch conditions, for CMC panels coated with either a homogeneous YSZ layer (red) or a dual layer emitter/reflector geometry (blue) of comparable total thickness FIG. 24 compares back-side temperatures of a multilayer sample with a single layer YSZ sample. Even though the single layer sample thickness is greater than the total thickness of the multilayer structure, back temperature of the multilayer sample is up to 80° C. lower for the same heat flux (torch settings) conditions.

Although various embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed is:

1. A multi-layer thermal protection material comprising:
a substrate layer;
a reflection layer formed on the substrate layer, said reflection layer comprising a porous scattering media effective to reflect photonic energy away from the substrate layer; and
an emission layer formed on the reflection layer and effective to convert thermal energy to photonic energy, said emission layer comprising a thermally emissive dopant incorporated into a thermal matrix material.

2. The material according to claim 1, wherein said material has a bulk thermal conductivity of between about 0.1 and about 3.0 W/m·K.

3. The material according to claim 1, wherein said substrate layer comprises a ceramic, a ceramic matrix composite, a metal, or combinations thereof.

4. The material according to claim 1, wherein said reflection layer comprises a porous ceramic, a metal, or combinations thereof.

5. The material according to claim 4, wherein said porous ceramic is selected from the group consisting of porous yttrium-stabilized zirconia (YSZ), porous yttrium-stabilized hafnia, porous calcium-stabilized zirconia, porous lanthanide-stabilized zirconia, porous lanthanide-stabilized hafnia, and porous magnesia.

6. The material according to claim 1, wherein said reflection layer has a grey emissivity of between about 0.4 and about 1.0, and a thermal conductivity of between about 0.1 and about 3.0 W/m·K.

7. The material according to claim 1, wherein said thermal matrix material is transparent to dominant wavelengths radiated by the thermally emissive dopant.

8. The material according to claim 1, wherein said thermal matrix material is selected from the group consisting of yttria-stabilized zirconia (YSZ), yttrium-stabilized hafnia, lanthanide-stabilized zirconia, lanthanide-stabilized hafnia, calcium-stabilized zirconia, and calcium-stabilized hafnia.

9. The material according to claim 1, wherein said thermally emissive dopant comprises an element selected from the group consisting of cerium (Ce), nickel (Ni), holmium (Ho), neodymium (Nd), samarium (Sm), erbium (Er), ytterbium (Yb), thulium (Tm), cobalt (Co), and mixtures thereof.

10. The material according to claim 1, wherein said thermally emissive dopant is selected from the group consisting of CeO₂, Nd₂O₃, Sm₂O₃, Er₂O₃, Yb₂O₃, Tm₂O₃, Co₃O₄, and NiO.

11. The material according to claim 1, wherein said emission layer comprises a doped ceramic.

12. The material according to claim 11, wherein said doped ceramic is selected from the group consisting of CeO₂-doped YSZ, cerium-doped hafnia, lanthanide-doped hafnia, and lanthanide doped zirconia.

13. The material according to claim 1, wherein said emission layer has a grey emissivity of between about 0.7 and about 1.0, and a thermal conductivity of between about 0.1 and about 3.0 W/m·K.

14. The material according to claim 1, wherein said emission layer has a surface that is either textured or non-textured.

15. The material according to claim 14, wherein the surface of the emission layer is textured and has features on the order of 50-500 μm depth and 50-500 μm width.

16. The material according to claim 1, wherein said emission layer has a micro-textured surface effective to absorb acoustic energy.

17. The material according to claim 1, wherein said material has an overall thickness of between about 100 and about 5,000 micrometers, and the emissive layer has a thickness of between about 5 and about 250 micrometers.

18. The material according to claim 1 further comprising:
one or more interfacial layers interposed between the substrate layer and the reflection layer to minimize thermal expansion coefficient mismatch between the substrate layer and the reflective layer.

19. An article comprising:
a base; and
the multi-layer thermal protection material according to claim 1 formed on said base, wherein the substrate layer of the multi-layer thermal protection material is proximate to the base.

20. The article according to claim 19 further comprising:
a bonding layer formed between the base and the substrate layer of the multi-layer thermal protection material.

21. The article according to claim 19, wherein the base comprises at least a portion of a surface of a hypersonic flight vehicle, a component part of a turbine engine, or surface exposed to a hot gas environment.

22. The article according to claim 21, wherein the component part of the turbine engine is selected from the group consisting of a nozzle, a turbine blade, a vane, a combustion liner, a shroud, a bucket, and a transition piece.

23. A method for producing a thermally protected article, said method comprising the steps of:
providing a base having an outer surface; and
forming the multi-layer thermal protection material according to claim 1 on said base,
wherein the multi-layer thermal protection material is layered onto the base beginning with the substrate layer.

24. The method according to claim 23, wherein the multi-layer thermal protection material is formed on the base by deposition techniques selected from the group consisting of solution plasma spray, powder plasma spray, chemical vapor deposition, dip-coating, spin casting, and combinations thereof.

25. The method according to claim 23 further comprising:
forming a bonding layer between the base and the multi-layer thermal protection material.

26. The method according to claim 23, wherein the base comprises at least a portion of a surface of a hypersonic flight vehicle, a component part of a turbine engine, or surface exposed to a hot gas environment.

27. The method according to claim 26, wherein the component part of the turbine engine is selected from the group consisting of a nozzle, a turbine blade, a vane, a combustion liner, a shroud, a bucket, and a transition piece.
